(19) United States
(12) Patent Application Publication
(10) Pub. No.: US 2026/0193775 A1
(43) Pub. Date: Jul. 9, 2026

(54) PREPARATION OF LANTHANIDE ELEMENT-CONTAINING VOLATILE PRECURSORS AND DEPOSITION OF LANTHANIDE ELEMENT-CONTAINING FILMS USING THE SAME

(71) Applicant: L'Air Liquide, Société Anonyme pour I'Etude et I'Exploitationdes Procédés Georges Claude, Paris (FR)

(72) Inventors: Junhyun SONG, Seoul (KR); Wontae NOH, Seoul (KR)

(21) Appl. No.: 19/009,684

(22) Filed: Jan. 3, 2025

(51) Int. Cl. C23C 16/40; C23C 16/455; H01L 21/285

(52) U.S. Cl. CPC C23C 16/40; C23C 16/45553; H10P 14/40

(57) ABSTRACT

A method of forming a lanthanide element-containing film on a substrate comprises the steps of:
exposing the substrate to a vapor of a lanthanide element-containing film forming composition that contains a lanthanide element-containing precursor having the formula:

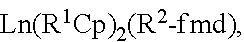

wherein R²-fmd is a formamidinate group, R²NC(H)═NR², wherein the R² group can be the same or different; Cp is cyclopentadienyl; Ln is a lanthanide element selected from Sc, Y, La, Ce, Pr, Nd, Pm, Sm, Eu, Gd, Tb, Dy, Ho, Er, Tm, Yb or Lu; R¹ and R² each are independently selected from a hydrogen atom, a C₁ to C₅ linear or branched alkyl-group, a C₃ to C₅ cyclic alkyl-group; and
depositing at least part of the lanthanide element-containing precursor onto the substrate to form the lanthanide element-containing film via a vapor deposition process.

### TECHNICAL FIELD

The present invention relates to methods for preparation of lanthanide element-containing volatile precursors and methods of using the same to deposit lanthanide element-containing film. More specifically, the disclosed methods are syntheses of the lanthanide element-containing volatile precursors using lanthanide halogens, n-BuLi and formamidinate and deposition of the lanthanide element containing film using the lanthanide element containing volatile precursors.

### BACKGROUND

Thin-film transistor (TFT) technology is a type of field-effect transistor (FET) that uses thin films of materials to create active elements in displays and other devices, including integrated circuits and displays used in screens for electronic products, such as car instrument clusters, televisions, computer monitors, video games, mobile phones, notebook computers, digital cameras, and personal digital assistances. The TFTs serve as switching elements for each pixel unit in the display device. The TFT stack typically includes, at a minimum, a substrate, a gate electrode, a dielectric or insulating layer, source and drain electrodes, and a semiconductor channel layer.

Many TFT stacks now include semiconductor channel layers, InZnO (Barquinha et al., J. Non-Crystalline Sol. 2006, 352, 1749-1752), InGaZnO (Wang et al., IEEE Trans. Electron. Devices 2011, 58, 480-485), InSnZnO (Wang et al., Nanomaterials 2020, 10, 617), and InGaSnO (Kim et al., Electronics 2021, 10, 1295). For example, the InGaZnO semiconductor channel layer provides many advantages, such as room-temperature process availability, high optical transparency, high stability, high mobility and good-uniformity. In InGaZnO-TFTs, both the InGaZnO channel layer and insulating layer play a crucial role in the TFT performance.

Lanthanide-doped indium zinc oxide (Ln-IZO) was employed as the active channel layer (ACT) of TFTs (Xiao et al., Available at SSRN: https://ssrn.com/abstract=4478405 or http://dx.doi.org/10.2139/ssrn.4478405)

Ln₂O₅, wherein Ln is a lanthanide element, has been proposed as suitable TFT dielectric insulating materials (Moon et al., J. Korean Physical Society, Vol. 55, No. 5, pp. 1906-1909, 2009). The Ln₂O₅ films are expected to be suitable for TFT dielectric insulating materials due to its high dielectric constant (~10.8).

US20130303739 to Pallem et al. discloses preparation of lanthanide element-containing precursors and deposition of lanthanide element-containing films in which the precursors include Y(iPrCp)₂(N iPr-amd), Dy(iPrCp)₂(N iPr-amd), Er(MeCp)₂(N iPr-amd). Gd(iPrCp)₂(N iPr-amd) and Yb(EtCp)₂(N iPr-fmd). A series of M(RCp)₂(R′-amd) derivatives (amd=amidinate) is developed.

In the meantime, a M(RCp)₂(R′-fmd) (fmd=formamidinate) (U.S. Pat. Nos. 8,283,201 and 9,711,347) backbone has been applied to other lanthanide element such as scandium and yttrium to synthesize successfully Sc and Y series, demonstrating good improvement of volatility and superior ALD behavior in terms of low, impurities, non-uniformity and step coverage, compared to Sc(RCp)₂(iPr-amd) and Y(RCp)₂(iPr-amd).

US20160315168 to Dussarrat et al. discloses process for forming gate insulators for TFT structures. The Lanthanide element-containing precursor having the formula: Ln(RCp)₂(NiPr Me-amd). The exemplary Lanthanide element-containing precursor is selected from the group consisting of Er(MeCp)₂(NiPr-fmd), Yb(EtCp)₂(NiPr-fmd), Yb(iPrCp)₂(NiPr-fmd), and combinations thereof.

US20160293409 A1 to Pallem et al. discloses preparation of lanthanide element-containing precursors and deposition of lanthanide element-containing films, in which lanthanide element-containing precursors having the formula: Ln(R¹Cp)ₘ(R²—N—C(R⁴)═N—R²)ₙ, wherein: Ln is a lanthanide metal having an ionic radius from approximately 0.75 \acute{Å} to approximately 0.94 \acute{Å}, a 3+ charge, and a coordination number of 6; R¹ is selected from the group consisting of H and a C₁-C₅ alkyl chain; R² is selected from the group consisting of H and a C₁-C₅ alkyl chain; R⁴ is selected from the group consisting of H and Me; n and m range from 1 to 2; and the precursor has a melting point below approximately 105° C.

In addition, there are still several drawbacks for high-k gate insulators produced by physical vapor deposition (PVD) based technologies such as large leakage current and surface roughness, which lead to reduction of the mobility, and instability (Ding et al., Microelectronics Reliability, 54 (2014) 2401-2405).

Consequently, a need remains for low temperature (e. g., below 500° C.) vapor deposition processes of a dielectric insulating layer of the TFT.

### SUMMARY

Disclosed is a method of forming a lanthanide element-containing film on a substrate, the method comprising the steps of:
exposing the substrate to a vapor of a lanthanide element-containing film forming composition that contains a lanthanide element-containing precursor having the formula:

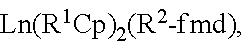

wherein R²-fmd is a formamidinate group, R²NC(H)═NR², wherein the R² group can be the same or different; Cp is cyclopentadienyl; Ln is a lanthanide element selected from Sc, Y, La, Ce, Pr, Nd, Pm, Sm, Eu, Gd, Tb, Dy, Ho, Er, Tm, Yb or Lu; R¹ and R² each are independently selected from a hydrogen atom, a C₁ to C₅ linear or branched alkyl-group, a C₃ to C₅ cyclic alkyl-group; and
depositing at least part of the lanthanide element-containing precursor onto the substrate to form the lanthanide element-containing film via a vapor deposition process.

The disclosed deposition method may include one or more of the following features:
R² being defined an alkyl group;
R² being selected from Me, Et, nPr, iPr, nBu, iBi, sBu or tBu;
the lanthanide element-containing precursor being selected from the group consisting of GdCp₂(iPr-fmd), Dy(EtCp)₂(iPr-fmd) and Dy(MeCp)₂(iPr-fmd);
the lanthanide element-containing precursor being GdCp₂(iPr-fmd);
the lanthanide element-containing precursor being Dy(EtCp)₂(iPr-fmd);
the lanthanide element-containing precursor being Dy(MeCp)₂(iPr-fmd);
further comprising exposing the substrate to a co-reactant selected from an oxidizer agent or a nitrogen agent;
the co-reactant being selected from O₃, O₂, H₂O, H₂O₂, D₂O, ROH wherein R═C₁-C₁₀ linear or branched hydrocarbon, or combination thereof;
the lanthanide element-containing precursor being volatile;
the lanthanide element-containing precursor being mixed with a solvent;
the solvent being a substituted or unsubstituted hydrocarbon selected from alkanes, alkenes, alkynes; alcohols selected from alkyl alcohols, amino alcohols; or amines selected from primary-, secondary-, tertiary-amines; tetrahydrofuran; dichloromethane; ethyl acetate; butyl acetate; acetonitrile; dimethylformamide;
the substituted or unsubstituted hydrocarbons including octane, ethyl benzene, xylene, mesitylene, decalin, decane, dodecane;
a concentration of the lanthanide element-containing precursor in the solvent ranging from approximately 50% w/w and approximately 100.0% w/w;
the substrate being exposed to the vapor of the lanthanide element-containing film forming composition at a temperature ranging from 150° C. to approximately 500° C.;
the temperature of the substrate remaining less than or equal to 450° C.;
the deposition temperature ranging from 150° C. to approximately 500° C.;
the deposition temperature remaining less than or equal to 450° C.;
the vapor deposition process being a MOCVD process, or an ALD process selected from a thermal ALD, spatial ALD, temporal ALD, or plasma ALD process;
the lanthanide element-containing film being a GyO film; and
the lanthanide element-containing film being a GaO film.

Also disclosed is a method of forming a conductive layer for a thin-film transistor (TFT) or transducer on a substrate, the method comprising the steps of:
exposing the substrate to a vapor of a lanthanide element-containing film forming composition that contains a lanthanide element-containing precursor having the formula:

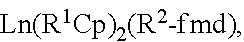

wherein R²-fmd is a formamidinate group, R²NC(H)═NR², wherein the R² group can be the same or different; Cp is cyclopentadienyl; Ln is a lanthanide element selected from Sc, Y, La, Ce, Pr, Nd, Pm, Sm, Eu, Gd, Tb, Dy, Ho, Er, Tm, Yb or Lu; R¹ and R² each are independently selected from a hydrogen atom, a C₁ to C₅ linear or branched alkyl-group, a C₃ to C₅ cyclic alkyl-group; and
depositing at least part of the lanthanide element-containing precursor onto the substrate to form the conductive layer for a thin-film transistor (TFT) or transducer via a vapor deposition process. The disclosed deposition method may include one or more of the following features:
R₂ being defined an alkyl group;
R₂ being selected from Me, Et, nPr, iPr, nBu, iBi, sBu or tBu;
the lanthanide element-containing precursor being selected from the group consisting of GdCp₂(iPr-fmd), Dy(EtCp)₂(iPr-fmd) and Dy(MeCp)₂(iPr-fmd);
the lanthanide element-containing precursor being GdCp₂(iPr-fmd);
the lanthanide element-containing precursor being Dy(EtCp)₂(iPr-fmd);
the lanthanide element-containing precursor being Dy(MeCp)₂(iPr-fmd);
further comprising exposing the substrate to a co-reactant selected from an oxidizer agent or a nitrogen agent;
the co-reactant being selected from O₃, O₂, H₂O, H₂O₂, D₂O, ROH wherein R═C₁-C₁₀ linear or branched hydrocarbon, or combination thereof;
the lanthanide element-containing precursor being volatile;
the lanthanide element-containing precursor being mixed with a solvent;
the solvent being a substituted or unsubstituted hydrocarbon selected from alkanes, alkenes, alkynes; alcohols selected from alkyl alcohols, amino alcohols; or amines selected from primary-, secondary-, tertiary-amines; tetrahydrofuran; dichloromethane; ethyl acetate; butyl acetate; acetonitrile; dimethylformamide;
the substituted or unsubstituted hydrocarbons including octane, ethyl benzene, xylene, mesitylene, decalin, decane, dodecane;
a concentration of the lanthanide element-containing precursor in the solvent ranging from approximately 50% w/w and approximately 100.0% w/w;
the substrate being exposed to the vapor of the lanthanide element-containing film forming composition at a temperature ranging from 150° C. to approximately 500° C.;
the temperature of the substrate remaining less than or equal to 450° C.;
the deposition temperature ranging from 150° C. to approximately 500° C.;
the deposition temperature remaining less than or equal to 450° C.;
the vapor deposition process being a MOCVD process, or an ALD process selected from a thermal ALD, spatial ALD, temporal ALD, or plasma ALD process;
the lanthanide element-containing film being a Gyor film; and
the lanthanide element-containing film being a Gao film.

Also disclosed is a lanthanide element-containing film-forming composition for forming a lanthanide element-containing film, the composition comprising:
i) at least one lanthanide element-containing precursor, wherein the lanthanide element-containing precursor having the formula:

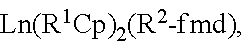

wherein R²-fmd is a formamidinate group, R²NC(H)═NR², wherein the R² group can be the same or different; Cp is cyclopentadienyl; Ln is a lanthanide element selected from Sc, Y, La, Ce, Pr, Nd, Pm, Sm, Eu, Gd, Tb, Dy, Ho, Er, Tm, Yb or Lu; R¹ and R² each are independently selected from a hydrogen atom, a C₁ to C₅ linear or branched alkyl-group, a C₃ to C₅ cyclic alkyl-group;
ii) a co-reactant; and
iii) a solvent,
   wherein the lanthanide-containing film-forming composition is capable of forming the lanthanide element-containing film. The disclosed lanthanide element-containing film-forming composition may include one or more of the following features:
R² being defined an alkyl group;
R² being selected from Me, Et, nPr, iPr, nBu, iBi, sBu or tBu;
the at least one lanthanide element-containing precursor being selected from the group consisting of GdCp₂(iPr-fmd), Dy(EtCp)₂(iPr-fmd) and Dy(MeCp)₂(iPr-fmd);
the lanthanide element-containing precursor being volatile;
the solvent being THT, hexane or toluene; and
a purity of the composition being greater than 95% w/w (i.e., 95.0% w/w to 100.0% w/w).

### Notation and Nomenclature

The following detailed description and claims utilize a number of abbreviations, symbols, and terms, which are generally well known in the art. Certain abbreviations, symbols, and terms are used throughout the following description and claims, and include:

As used herein, the indefinite article “a” or “an” means one or more.

As used herein, “about” or “around” or “approximately” in the text or in a claim means ±10% of the value stated.

As used herein, “room temperature” in the text or in a claim means from approximately 20° C. to approximately 25° C.

The term “ambient temperature” refers to an environment temperature approximately 20° C. to approximately 30° C.

The term “substrate” refers to a material or materials on which a process is conducted. The substrate may refer to a wafer having a material or materials on which a process is conducted. The substrates may be any suitable wafer used in semiconductor, photovoltaic, flat panel, or LCD-TFT device manufacturing. The substrate may also have one or more layers of differing materials already deposited upon it from a previous manufacturing step. For example, the wafers may include silicon layers (e.g., crystalline, amorphous, porous, etc.), silicon containing layers (e.g., SiO₂, SiN, SiON, SiCOH, etc.), metal containing layers (e.g., copper, cobalt, ruthenium, tungsten, platinum, palladium, nickel, ruthenium, gold, etc.) or combinations thereof. Furthermore, the substrate may be planar or patterned. The substrate may be an organic patterned photoresist film. The substrate may include layers of oxides which are used as dielectric materials in MEMS, 3D NAND, MIM, DRAM, or FeRam device applications (for example, ZrO₂ based materials, HfO₂ based materials, TiO₂ based materials, rare earth oxide based materials, ternary oxide based materials, etc.) or nitride-based films (for example, TaN, TIN, NbN) that are used as electrodes. One of ordinary skill in the art will recognize that the terms “film” or “layer” used herein refer to a thickness of some material laid on or spread over a surface and that the surface may be a trench or a line. Throughout the specification and claims, the wafer and any associated layers thereon are referred to as substrates.

The term “wafer” or “patterned wafer” refers to a wafer having a stack of films on a substrate and at least the top-most film having topographic features that have been created in steps prior to the deposition of the indium containing film.

The term “aspect ratio” refers to a ratio of the height of a trench (or aperture) to the width of the trench (or the diameter of the aperture).

The term “high aspect ratio” refers to an aspect ratio larger than approximately 2:1, preferably an aspect ratio ranging from approximately 2:1 to approximately 200:1.

Note that herein, the terms “film” and “layer” may be used interchangeably. It is understood that a film may correspond to, or related to a layer, and that the layer may refer to the film. Furthermore, one of ordinary skill in the art will recognize that the terms “film” or “layer” used herein refer to a thickness of some material laid on or spread over a surface and that the surface may range from as large as the entire wafer to as small as a trench or a line.

Note that herein, the terms “aperture”, “via”, “hole” and “trench” may be used interchangeably to refer to an opening formed in a semiconductor structure.

As used herein, the abbreviation “NAND” refers to a “Negative AND” or “Not AND” gate; the abbreviation “2D” refers to 2 dimensional gate structures on a planar substrate; the abbreviation “3D” refers to 3 dimensional or vertical gate structures, wherein the gate structures are stacked in the vertical direction.

Note that herein, the terms “deposition temperature” and “substrate temperature” may be used interchangeably. It is understood that a substrate temperature may correspond to, or be related to a deposition temperature, and that the deposition temperature may refer to the substrate temperature.

Note that herein, the terms “precursor” and “deposition compound” and “deposition gas” may be used interchangeably when the precursor is in a gaseous state at room temperature and ambient pressure. It is understood that a precursor may correspond to, or be related to a deposition compound or deposition gas, and that the deposition compound or deposition gas may refer to the precursor.

The term “film-forming composition” refers to a composition used for deposition of a film. The film-forming composition may include, but is not limited to, a precursor, a solvent and/or a carrier gas. Furthermore, the film-forming composition may include, but is not limited to, a precursor, optionally a solvent, optionally a carrier gas, and optionally one or more co-reactant(s). Herein, the precursor may be supplied either in a neat form or in a blend with a suitable solvent. The precursor may be present in varying concentrations in the solvent. Alternatively, the precursor may be vaporized by passing a carrier gas into a container that contains the precursor or by bubbling the carrier gas into the precursor. The carrier gas and precursor are then introduced into a reactor as a vapor. The co-reactant may be an oxidizer, a reducing agent, a dilute gas, an additive, an inhibitor, an additional or a secondary precursor, etc., for assisting in formation of the film. Here an inert gas selected from N₂, He, Ar, Kr, Xe may be used as the carrier gas and/or the dilute gas.

The standard abbreviations of the elements from the periodic table of elements are used herein. It should be understood that elements may be referred to by these abbreviation (e.g., Si refers to silicon, N refers to nitrogen, O refers to oxygen, C refers to carbon, H refers to hydrogen, F refers to fluorine, etc.).

The unique CAS registry numbers (i.e., “CAS”) assigned by the Chemical Abstract Service are provided to identify the specific molecules disclosed.

Please note that the films or layers deposited, such as silicon oxide or silicon nitride, may be listed throughout the specification and claims without reference to their proper stoichiometry (i.e., SiO, SiO₂, Si₃N₄). The layers may include pure (Si) layers, carbide (SiₒCₚ) layers, nitride (SiₖNₗ) layers, oxide (SiₙOₘ) layers, or mixtures thereof, wherein k, l, m, n, o, and p inclusively range from 1 to 6. For instance, silicon oxide is SiₙOₘ, wherein n ranges from 0.5 to 1.5 and m ranges from 1.5 to 3.5. More preferably, the silicon oxide layer is SiO or SiO₂. The silicon oxide layer may be a silicon oxide based dielectric material, such as organic based or silicon oxide based low-k dielectric materials such as the Black Diamond II or III material by Applied Materials, Inc. Alternatively, any referenced silicon-containing layer may be pure silicon. Any silicon-containing layers may also include dopants, such as B, C, P, As and/or Ge.

Certain abbreviations are used throughout the following description and claims and include: the abbreviation “Ln” refers to the lanthanide group, which includes the following elements: scandium (“Sc”), yttrium (“Y”), lutetium (“Lu”), lanthanum (“La”), cerium (“Ce”), praseodymium (“Pr”), neodymium (“Nd”), samarium (“Sm”), europium (“Eu”), gadolinium (“Gd”), terbium (“Tb”), dysprosium (“Dy”), holmium (“Ho”), erbium (“Er”), thulium (“Tm”), or ytterbium (“Yb”); the abbreviation “Cp” refers to cyclopentadiene; the abbreviation “Å” refers to angstroms; prime (“′”) is used to indicate a different component than the first, for example (LnLn′O₃ refers to a lanthanide oxide containing two different lanthanide elements; the term “aliphatic group” refers to a C₁-C₅ linear or branched chain alkyl group; the term “alkyl group” refers to saturated functional groups containing exclusively carbon and hydrogen atoms; the abbreviation “Me” refers to a methyl group; the abbreviation “Et” refers to an ethyl group; the abbreviation “Pr” refers to a propyl group; the abbreviation “iPr” refers to an isopropyl group; the abbreviation “tBu” refers to a tertiary butyl group; the abbreviation “MIM” refers to Metal Insulator Metal (a structure used in capacitors); the abbreviation “DRAM” refers to dynamic random access memory; the abbreviation “FeRAM” refers to ferroelectric random access memory; the abbreviation “CMOS” refers to complementary metal-oxide-semiconductor; the abbreviation “THF” refers to tetrahydrofuran; the abbreviation “TGA” refers to thermogravimetric analysis.

As used herein, the term “hydrocarbon” refers to a saturated or unsaturated function group containing exclusively carbon and hydrogen atoms. As used herein, the term “alkyl group” refers to saturated functional groups containing exclusively carbon and hydrogen atoms. An alkyl group is one type of hydrocarbon. Further, the term “alkyl group” refers to linear, branched, or cyclic alkyl groups. Examples of linear alkyl groups include without limitation, methyl groups, ethyl groups, propyl groups, butyl groups, etc. Examples of branched alkyls groups include without limitation, t-butyl. Examples of cyclic alkyl groups include without limitation, cyclopropyl groups, cyclopentyl groups, cyclohexyl groups, etc.

As used herein, the term “alkyl group” refers to saturated functional groups containing exclusively carbon and hydrogen atoms. Further, the term “alkyl group” refers to linear, branched, or cyclic alkyl groups. Examples of linear alkyl groups include without limitation, methyl groups, ethyl groups, propyl groups, butyl groups, etc. Examples of branched alkyls groups include without limitation, t-butyl. Examples of cyclic alkyl groups include without limitation, cyclopropyl groups, cyclopentyl groups, cyclohexyl groups, etc.

As used herein, the abbreviation “Me” refers to a methyl group; the abbreviation “Et” refers to an ethyl group; the abbreviation “Pr” refers to a propyl group; the abbreviation “nPr” refers to a “normal” or linear propyl group; the abbreviation “iPr” refers to an isopropyl group; the abbreviation “Bu” refers to a butyl group; the abbreviation “nBu” refers to a “normal” or linear butyl group; the abbreviation “tBu” refers to a tert-butyl group, also known as 1,1-dimethylethyl; the abbreviation “sBu” refers to a sec-butyl group, also known as 1-methylpropyl; the abbreviation “iBu” refers to an iso-butyl group, also known as 2-methylpropyl; the abbreviation “amyl” refers to an amyl or pentyl group; the abbreviation “tAmyl” refers to a tert-amyl group, also known as 1,1-dimethylpropyl.

The standard abbreviations of the elements from the periodic table of elements are used herein. It should be understood that elements may be referred to by these abbreviations (e.g., Si refers to silicon, N refers to nitrogen, O refers to oxygen, C refers to carbon, etc.).

As used herein, the abbreviation “R-amd” refers to the amidinate ligand RNC(R′)═NR, wherein R and R′ each are defined a hydrogen, an alkyl group, i.e., a C₁ to C₅ linear or branched alkyl-group, a C₃ to C₅ cyclic alkyl-group, such as Me, Et, nPr, iPr, nBu, iBi, sBu or tBu, and the R′ group and the two R groups can be the same or different. In addition, in some embodiments, “R-amd” may represent RNC(CH₃)═NR ligand, when R′ is a CH₃ (Me) group. For example, “iPr-amd” may represent iPrNC(CH₃)═NiPr ligand. As used herein, the abbreviation “R-fmd” refers to the form formamidinate ligand RNC(H)═NR, wherein R is defined an alkyl group, i.e., a C₁ to C₅ linear or branched alkyl-group, a C₃ to C₅ cyclic alkyl-group, such as Me, Et, nPr, iPr, nBu, iBi, sBu or tBu; and the R groups can be the same or different. For example, “iPr-fmd” represents iPrNC(H)═NiPr ligand. Although depicted here as having a double bond between the C and N of the ligand backbone, one of ordinary skill in the art will recognize that the amidinate, forming iodinate and guanidinate ligands, does not contain a fixed double bond. Instead, one electron is delocalized amongst the N—C—N chain. The same as the formamidinate.

Ranges may be expressed herein as from about one particular value, and/or to about another particular value. When such a range is expressed, it is to be understood that another embodiment is from the one particular value and/or to the other particular value, along with all combinations within said range. Any and all ranges recited herein are inclusive of their endpoints (i.e., x=1 to 4 or x ranges from 1 to 4 includes x=1, x=4, and x=any number in between), irrespective of whether the term “inclusively” is used.

Reference herein to “one embodiment” or “an embodiment” means that a particular feature, structure, or characteristic described in connection with the embodiment may be included in at least one embodiment of the invention. The appearances of the phrase “in one embodiment” in various places in the specification are not necessarily all referring to the same embodiment, nor are separate or alternative embodiments necessarily mutually exclusive of other embodiments. The same applies to the term “implementation.”

As used herein, the term “independently” when used in the context of describing R groups should be understood to denote that the subject R group is not only independently selected relative to other R groups bearing the same or different subscripts or superscripts, but is also independently selected relative to any additional species of that same R group. For example in the formula MR¹ₓ (NR²R³)₍₄₋ₓ₎, where x is 2 or 3, the two or three R¹ groups may, but need not be identical to each other or to R² or to R³. Further, it should be understood that unless specifically stated otherwise, values of R groups are independent of each other when used in different formulas.

As used in this application, the word “exemplary” is used herein to mean serving as an example, instance, or illustration. Any aspect or design described herein as “exemplary” is not necessarily to be construed as preferred or advantageous over other aspects or designs. Rather, use of the word exemplary is intended to present concepts in a concrete fashion.

Additionally, the term “or” is intended to mean an inclusive “or” rather than an exclusive “or”. That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims should generally be construed to mean “one or more” unless specified otherwise or clear from context to be directed to a singular form.

“Comprising” in a claim is an open transitional term which means the subsequently identified claim elements are a nonexclusive listing (i.e., anything else may be additionally included and remain within the scope of “comprising”). “Comprising” is defined herein as necessarily encompassing the more limited transitional terms “consisting essentially of” and “consisting of”; “comprising” may therefore be replaced by “consisting essentially of” or “consisting of” and remain within the expressly defined scope of “comprising”.

“Providing” in a claim is defined to mean furnishing, supplying, making available, or preparing something. The step may be performed by any actors in the absence of express language in the claim to the contrary.

### BRIEF DESCRIPTION OF THE DRAWINGS

For a further understanding of the nature and objects of the present invention, reference should be made to the following detailed description, taken in conjunction with the accompanying drawings, in which like elements are given the same or analogous reference numbers and wherein:

FIG. 1 is TGA graph for GdCp₂(iPr-fmd);

FIG. 2 is TGA graph for Dy(EtCp)₂(iPr-fmd); and

FIG. 3 is TGA graph for Dy(MeCp)₂(iPr-fmd).

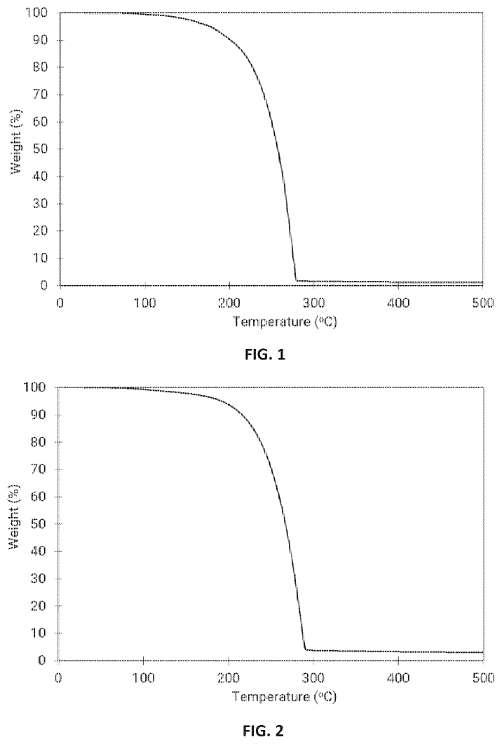

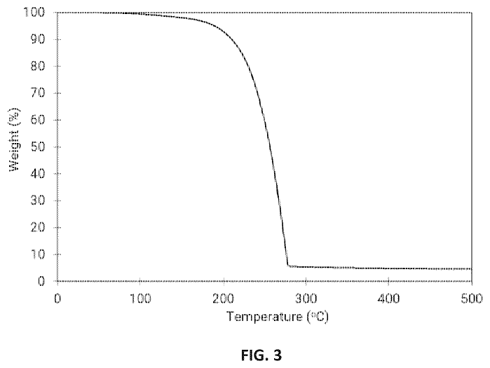

### DESCRIPTION OF PREFERRED EMBODIMENTS

Disclosed are methods for preparation of lanthanide element-containing volatile precursors in lanthanide element containing film forming compositions and methods of using the same to deposit lanthanide element-containing film in semiconductor industry. More specifically, the disclosed methods are syntheses of the lanthanide element-containing volatile precursors with lanthanide halogen and deposition of the lanthanide element containing film using the lanthanide element containing volatile precursors.

The disclosed lanthanide element-containing precursors having the general formula:

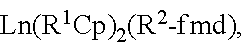

wherein R²-fmd is a formamidinate group, R²NC(H)═NR², wherein the R² group can be the same or different; Cp is cyclopentadienyl; Ln is a lanthanide element selected from Sc, Y, La, Ce, Pr, Nd, Pm, Sm, Eu, Gd, Tb, Dy, Ho, Er, Tm, Yb or Lu; R¹ and R² each are independently selected from a hydrogen atom, a C₁ to C₅ linear or branched alkyl-group, a C₃ to C₅ cyclic alkyl-group. Preferably, R² is an alkyl group, such as Me, Et, nPr, iPr, nBu, iBi, sBu or tBu.

The lanthanide element-containing precursors may be Gy or Gd precursors or lanthanide element-containing precursors selected from La to Lu (La, Ce, Pr, Nd, Pm, Sm, Eu, Gd, Tb, Dy, Ho, Er, Tm, Yb or Lu) precursors.

The Gy or Gd precursors or lanthanide element-containing precursors disclosed herein, such as Gd(RCp)₂(R′-fmd) and Dy(RCp)₂(R′-fmd), with —(R′-fmd) ligand, improve the volatility of the lanthanide element-containing precursors. Here R′ is selected from a hydrogen atom, a C₁ to C₅ linear or branched alkyl-group, a C₃ to C₅ cyclic alkyl-group. Preferably, R′ is an alkyl group, such as Me, Et, nPr, iPr, nBu, iBi, sBu or tBu.

In some embodiments, the lanthanide element-containing precursors may be Gd or Gy precursors.

In some embodiments, the lanthanide element-containing precursors may be Gd precursors.

In some embodiments, the lanthanide element-containing precursors may be Gy precursors.

Exemplary lanthanide element-containing precursors include GdCp₂(iPr-fmd), Dy(EtCp)₂(iPr-fmd), and Dy(MeCp)₂(iPr-fmd). Here “iPr-fmd” represents iPrNC(H)═NiPr ligand.

The disclosed lanthanide element-containing precursor is GdCp₂(iPr-fmd).

The disclosed lanthanide element-containing precursor is Dy(EtCp)₂(iPr-fmd).

The disclosed lanthanide element-containing precursor is Dy(MeCp)₂(iPr-fmd).

The synthesis of the disclosed lanthanide element-containing precursors may be carried out by following methods with n-BuLi, lanthanide halogens and formamidinate:

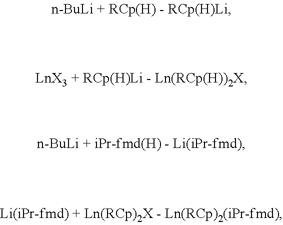

wherein iPr-fmd represents formamidinate ligand, iPrNC(H)═NiPr; Cp is cyclopentadienyl; Ln is an element in the lanthanide group selected from Sc, Y, La, Ce, Pr, Nd, Sm, Eu, Gd, Tb, Dy, Ho, Er, Tm, Yb, Lu; R is selected from a hydrogen atom, a C₁ to C₅ linear or branched alkyl-group, a C₃ to C₅ cyclic alkyl-group; X is halogen selected from F, Cl, Br or I.

The above reactions may be conducted in a temperature of from −78° C. to room temperature under atmosphere pressure in a solvent. The solvent is a substituted or unsubstituted hydrocarbon selected from alkanes, alkenes, alkynes; alcohols selected from alkyl alcohols, amino alcohols; or amines selected from primary-, secondary-, tertiary-amines; tetrahydrofuran; dichloromethane; ethyl acetate; butyl acetate; acetonitrile; dimethylformamide. The substituted or unsubstituted hydrocarbons include octane, ethyl benzene, xylene, mesitylene, decalin, decane, dodecane. The solvent may be THF, hexane, toluene, or the like.

Purity of the disclosed lanthanide element-containing film-forming composition including the disclosed lanthanide element-containing precursor is greater than 95% w/w (i.e., 95.0% w/w to 100.0% w/w), preferably greater than 98% w/w (i.e., 98.0% w/w to 100.0% w/w), and more preferably greater than 99% w/w (i.e., 99.0% w/w to 100.0% w/w). One of ordinary skill in the art will recognize that the purity may be determined by H NMR and gas liquid chromatography with mass spectrometry. The disclosed lanthanide element-containing film-forming composition may contain any of the following impurities: pyrazoles; pyridines; alkylamines; alkylamines; THF; ether; pentane; cyclohexane; heptanes; benzene; toluene; chlorinated metal compounds; lithium, sodium, potassium pyrazolyl. The total quantity of these impurities is preferably below 5% w/w (i.e., 0.0% w/w to 5.0% w/w), preferably below 2% w/w (i.e., 0.0% w/w to 2.0% w/w), and more preferably below 1% w/w (i.e., 0.0% w/w to 1.0% w/w). The composition may be purified by recrystallisation, sublimation, distillation, and/or passing the gas liquid through a suitable adsorbent, such as a 4 Å molecular sieve.

Purification of the disclosed lanthanide element-containing film-forming composition may also result in metal impurities at the 0 ppbw to 1 ppmw, preferably 0-500 ppbw (part per billion weight) level. These metal impurities may include, but are not limited to, Aluminum (Al), Arsenic (As), Barium (Ba), Beryllium (Be), Bismuth (Bi), Cadmium (Cd), Calcium (Ca), Chromium (Cr), Cobalt (Co), Copper (Cu), Gallium (Ga), Germanium (Ge), Hafnium (Hf), Zirconium (Zr), Indium (In), Iron (Fe), Lead (Pb), Lithium (Li), Magnesium (Mg), Manganese (Mn), Tungsten (W), Nickel (Ni), Potassium (K), Sodium (Na), Strontium (Sr), Thorium (Th), Tin (Sn), Titanium (Ti), Uranium (U), and Zinc (Zn).

The disclosed lanthanide element-containing precursor may be deposited to form lanthanide element-containing films using any deposition methods known to those of skill in the art. Examples of suitable deposition methods include without limitation, conventional chemical vapor deposition (CVD), low pressure chemical vapor deposition (LPCVD), atomic layer deposition (ALD), pulsed chemical vapor deposition (P-CVD), plasma enhanced atomic layer deposition (PE-ALD), or combinations thereof.

The type of substrate upon which the lanthanide element-containing film will be deposited will vary depending on the final use intended. In some embodiments, the substrate may be chosen from oxides which are used as dielectric materials in MIM, DRAM, FeRam technologies or gate dielectrics in CMOS technologies, for example, HfO₂ based materials, TiO₂ based materials, ZrO₂ based materials, rare earth oxide based materials, ternary oxide based materials, etc., or from nitride-based films (for example, TaN) that are used as an oxygen barrier between copper and the low-k layer. Other substrates may be used in the manufacture of semiconductors, photovoltaics, LCD-TFT, or flat panel devices. Examples of such substrates include, but are not limited to, solid substrates such as metal substrates (for example, Au, Pd, Rh, Ru, W, Al, Ni, Ti, Co, Pt and metal silicides, such as TiSi₂, CoSi₂, and NiSi2); metal nitride containing substrates (for example, TaN, TIN, WN, TaCN, TiCN, TaSiN, and TiSiN); semiconductor materials (for example, Si, SiGe, GaAs, InP, diamond, GaN, and SiC); insulators (for example, SiO₂, Si₃N₄, SiON, HfO₂, Ta₂O₅, ZrO₂, TiO₂, Al₂O₃, and barium strontium titanate); or other substrates that include any number of combinations of these materials. The actual substrate utilized may also depend upon the specific precursor embodiment utilized. In many instances though, the preferred substrate utilized will be selected from TIN, Ru, and Si type substrates.

The lanthanide element-containing precursor is introduced into a reaction chamber containing at least one substrate. The reaction chamber may be any enclosure or chamber of a device in which deposition methods take place, such as, without limitation, a parallel-plate type reactor, a cold-wall type reactor, a hot-wall type reactor, a single-wafer reactor, a multi-wafer reactor, or other such types of deposition systems

The reaction chamber may be maintained at a pressure ranging from about 0.5 mTorr to about 20 Torr. In addition, the temperature within the reaction chamber may range from about 150° C. to 500° C. One of ordinary skill in the art will recognize that the temperature may be optimized through mere experimentation to achieve the desired result.

The substrate may be heated to a sufficient temperature to obtain the desired lanthanide element-containing film at a sufficient growth rate and with desired physical state and composition. A non-limiting exemplary temperature range to which the substrate may be heated includes from 150° C. to 500° C. Preferably, the temperature of the substrate remains less than or equal to 450° C.

The lanthanide element-containing precursor may be fed in liquid state to a vaporizer where it is vaporized before it is introduced into the reaction chamber. Prior to its vaporization, the lanthanide element-containing precursor may optionally be mixed with one or more solvents, one or more metal sources, and a mixture of one or more solvents and one or more metal sources. The solvents may be selected from the group consisting of toluene, ethyl benzene, xylene, mesitylene, decane, dodecane, octane, hexane, pentane, or others. The resulting concentration may range from approximately 0.05 M to approximately 2 M. The metal source may include any metal precursors now known or later developed.

Alternatively, the lanthanide element-containing precursor may be vaporized by passing a carrier gas into a container containing the lanthanide element-containing precursor or by bubbling the carrier gas into the lanthanide element-containing precursor. The carrier gas and lanthanide element-containing precursor are then introduced into the reaction chamber. If necessary, the container may be heated to a temperature that permits the lanthanide element-containing precursor to be in its liquid phase and to have a sufficient vapor pressure. The carrier gas may include, but is not limited to, Ar, He, N₂, and mixtures thereof. The lanthanide element-containing precursor may optionally be mixed in the container with a solvent, another metal precursor, or a mixture thereof. The container may be maintained at temperatures in the range of, for example, 0-100° C. Those skilled in the art recognize that the temperature of the container may be adjusted in a known manner to control the amount of the lanthanide element-containing precursor vaporized.

In addition to the optional mixing of the lanthanide element-containing precursor with solvents, other metal precursors, and stabilizers if any prior to introduction into the reaction chamber, the lanthanide element-containing precursor may be mixed with reactant species inside the reaction chamber. Exemplary reactant species include, without limitation, H₂, metal precursors such as other lanthanide element-containing precursors, tris(diethylamido)(tert-butylimido)tantalum (V) (TBTDET), tris(diethylamido)(tert-butylimido) niobium (V) (TBTDEN), and any combinations thereof.

When the desired lanthanide element-containing film also contains oxygen, such as, for example and without limitation, erbium oxide, the reactant species may include an oxygen source which is selected from, but not limited to, O₂, O₃, H₂O, H₂O₂, acetic acid, formalin, para-formaldehyde, and combinations thereof.

When the desired lanthanide element-containing film also contains nitrogen, such as, for example and without limitation, erbium nitride or erbium carbo-nitride, the reactant species may include a nitrogen source which is selected from, but not limited to, nitrogen (N₂), ammonia and alkyl derivatives thereof, hydrazine and alkyl derivatives thereof, N-containing radicals (for instance N·, NH·, NH₂·), NO, N₂O, NO₂, amines, and any combination thereof.

When the desired lanthanide element-containing film also contains carbon, such as, for example and without limitation, erbium carbide or erbium carbo-nitride, the reactant species may include a carbon source which is selected from, but not limited to, methane, ethane, propane, butane, ethylene, propylene, t-butylene, isobutylene, CCl₄, and any combination thereof.

When the desired lanthanide element-containing film also contains silicon, such as, for example and without limitation, erbium silicide, erbium silico-nitride, erbium silicate, erbium silico-carbo-nitride, the reactant species may include a silicon source which is selected from, but not limited to, SiH₄, Si₂H₆, Si₃H₈, bis(diethylamino) silane (BDEAS), tris(dimethylamino)silane (TDMAS), (SiH₃)₃N, (SiH₃)₂O, trisilylamine, disiloxane, trisilylamine, disilane, trisilane, an alkoxysilane SiHₓ(OR¹)₄₋ₓ (x=1 to 4), a silanol Si(OH)ₓ(OR¹)₄₋ₓ (x=1 to 4) (preferably Si(OH)(OR¹)₃; more preferably Si(OH)(OtBu)₃), an aminosilane SiHₓ(NR¹R²)₄₋ₓ (where x is 1, 2, 3, or 4; R¹ and R² are independently H or a linear, branched or cyclic C₁-C₆ carbon chain; preferably bis(t-butylamino) silane (BTBAS), and/or Bis(diethylamino) silane (BDEAS), and any combinations thereof. The targeted film may alternatively contain Germanium (Ge), in which case the above-mentioned Si-containing reactant species could be replaced by Ge-containing reactant species.

When a desired lanthanide element-containing film also contains another metal, such as, for example and without limitation, Ti, Ta, Hf, Zr, Nb, Mg, Al, Sr, Y, Ba, Ca, As, Sb, Bi, Sn, Pb, or combinations thereof, the reactant species may include a metal source which is selected from, but not limited to, metal alkyls such as SbR₃ or SnR₄ (wherein each R is independently H or a linear or branched C₁-C₆ carbon chain, or cyclic C₃-C₆ carbon loop), metal alkoxides such as Sb(OR)₃ or Sn(OR)₄ (where each R is independently H or a linear or branched C₁-C₆ carbon chain, or cyclic C₃-C₆ carbon loop), and metal amines such as Sb(NR¹R²)(NR³R⁴)(NR⁵R⁶) or Ge(NR¹R²)(NR³R⁴)(NR⁵R⁶)(NR⁷R⁸) (where each R¹, R², R³, R⁴, R⁵, R⁶, R⁷, and R⁸ is independently H, a linear or branched C₁-C₆ carbon chain, a cyclic C₃-C₆ carbon loop, or a linear or cyclic trialkylsilyl group), and combinations thereof.

In addition to the disclosed lanthanide element-containing precursor, a co-reactant may be introduced into the reactor. When a target is a conductive film, the co-reactant may be H₂, H₂CO, N₂H₄, NH₃, a primary amine, a secondary amine, a tertiary amine, trisilylamine, a hydrazine N(SiH₃)₃, B₂H₆, Si₂H₆, radicals thereof, and mixtures thereof. Preferably, the co-reactant is H₂ or NH₃. Alternatively, when a target is a dielectric film, the co-reactant may be an oxidizing gas such as one of O₂, O₃, H₂O, H₂O₂, NO, N₂O, NO₂, oxygen containing radicals such as O—OH—, carboxylic acids, formic acid, acetic acid, propionic acid, and mixtures thereof. Preferably, the oxidizing gas is selected from the group consisting of O₃, H₂O₂ and H₂O.

The co-reactant may be treated by a plasma, in order to decompose the reactant into its radical form, N₂ may also be utilized as a nitrogen source gas when treated with plasma. For instance, the plasma may be generated with a power ranging from about 10 W to about 1000 W, preferably from about 50 W to about 500 W. The plasma may be generated present within the reactor itself. Alternatively, the plasma may generally be at a location removed from the reactor, for instance, in a remotely located plasma system. One of skill in the art will recognize methods and apparatus suitable for such plasma treatment.

For example, the co-reactant may be introduced into a direct plasma reactor, which generates plasma in the reaction chamber, to produce the plasma-treated reactant in the reaction chamber. The co-reactant may be introduced and held in the reaction chamber prior to plasma processing. Alternatively, the plasma processing may occur simultaneously with the introduction of the reactant. In-situ plasma is typically a 13.56 MHz RF inductively coupled plasma that is generated between the showerhead and the substrate holder. The substrate and the showerhead may be the powered electrode depending on whether positive ion impact occurs. Typical applied powers in in-situ plasma generators are from approximately 30 W to approximately 1000 W. Preferably, powers from approximately 30 W to approximately 600 W are used in the disclosed methods. More preferably, the powers range from approximately 100 W to approximately 500 W. The disassociation of the co-reactant using in-situ plasma is typically less than achieved using a remote plasma source for the same power input and is therefore not as efficient in reactant dissociation as a remote plasma system, which may be beneficial for the deposition of lanthanide element-containing films on substrates easily damaged by plasma.

Alternatively, the plasma-treated co-reactant may be produced outside of the reaction chamber, for example, a remote plasma to treat the co-reactant prior to passage into the reaction chamber.

The ALD conditions within the chamber allow the disclosed the lanthanide element-containing film-forming composition adsorbed chemisorbed on the substrate surface to react and form a lanthanide element-containing film on the substrate. In some embodiments, it is believed that plasma-treating the co-reactant may provide the co-reactant with the energy needed to react with the disclosed lanthanide element-containing film-forming composition.

Depending on what type of film is desired to be deposited, an additional precursor compound may be introduced into the reactor. The additional precursor may be used to provide additional elements to the lanthanide element-containing film. The additional elements may include Group I elements (lithium, Sodium, potassium), lanthanides (Ytterbium, Erbium, Dysprosium, Gadolinium, Praseodymium, Cerium, Lanthanum, Yttrium), Group IV elements (zirconium, titanium, hafnium), main group elements (germanium, silicon, aluminium), additional different Group V elements, and mixtures thereof. When an additional precursor compound and the lanthanide element-containing precursor is utilized, the resultant film deposited on the substrate contains lanthanide element-containing compositions in combination with an additional element from the additional precursor. When the additional precursor and the lanthanide element-containing precursors are used in more than one ALD super cycle sequences, a nanolaminate film is obtained.

The disclosed lanthanide element-containing precursor and one or more co-reactant may be introduced into the reaction chamber simultaneously (chemical vapor deposition), sequentially (atomic layer deposition), or in other combinations. For example, the lanthanide element-containing precursor may be introduced in one pulse and two additional metal sources may be introduced together in a separate pulse (modified atomic layer deposition). Alternatively, the reaction chamber may already contain the co-reactant prior to introduction of the lanthanide element-containing precursor. The reactant species may be passed through a plasma system localized remotely from the reaction chamber, and decomposed to radicals. Alternatively, the lanthanide element-containing precursor may be introduced to the reaction chamber continuously while other metal sources are introduced by pulse (pulsed-chemical vapor deposition). In each example, a pulse may be followed by a purge or evacuation step to remove excess amounts of the component introduced. In each example, the pulse may last for a time period ranging from about 0.01 s to about 10 s, alternatively from about 0.3 s to about 3 s, alternatively from about 0.5 s to about 2 s.

In one non-limiting exemplary atomic layer deposition type process, the vapor phase of a lanthanide element-containing precursor is introduced into the reaction chamber, where it is contacted with a suitable substrate. Excess lanthanide element-containing precursor may then be removed from the reaction chamber by purging and/or evacuating the reactor. An oxygen source is introduced into the reaction chamber where it reacts with the absorbed lanthanide precursor in a self-limiting manner. Any excess oxygen source is removed from the reaction chamber by purging and/or evacuating the reaction chamber. If the desired film is a lanthanide oxide film, this two-step process may provide the desired film thickness or may be repeated until a film having the necessary thickness has been obtained.

The lanthanide element-containing films or lanthanide element-containing layers resulting from the processes discussed above may include Ln₂O₃, (LnLn′)O₃, Ln₂O₃-Ln′₂O₃, LnSiₓO_{y}, LnGeₓO_{y}, (Al, Ga, Mn)LnO₃, HfLnOₓ or ZrLnOₓ. One of ordinary skill in the art will recognize that by judicial selection of the appropriate lanthanide element-containing precursor and co-reactant species, the desired film composition may be obtained.

Upon obtaining a desired film thickness, the film may be subject to further processing, such as thermal annealing, furnace-annealing, rapid thermal annealing, UV e-beam curing, and microwave annealing and/or plasma gas exposure. Those skilled in the art recognize the systems and methods utilized to perform these additional processing steps. For example, Ln₂O₃ film may be exposed to a temperature ranging from approximately 200° C. and approximately 1000° C. for a time ranging from approximately 0.1 second to approximately 7200 seconds under an inert atmosphere, an O-containing atmosphere, H-containing atmosphere combinations thereof. Most preferably, the temperature is 400° C. for 3600 seconds under an inert atmosphere or an O-containing atmosphere. The resulting film may contain fewer impurities and therefore may have an improved density resulting in improved leakage current. The annealing step may be performed in the same reaction chamber in which the deposition process is performed. Alternatively, the substrate may be removed from the reaction chamber, with the annealing/flash annealing process being performed in a separate apparatus. Any of the above post-treatment methods, but especially thermal annealing, has been found effective to reduce carbon and nitrogen contamination of Ln₂O₃ film. This in turn tends to improve the resistivity of the film.

After annealing, the lanthanide element-containing films deposited by any of the disclosed processes may have a bulk resistivity at room temperature of approximately 50 μohm·cm to approximately 1,000 μohm·cm. Room temperature is approximately 20° C. to approximately 28° C. depending on the season. Bulk resistivity is also known as volume resistivity. One of ordinary skill in the art will recognize that the bulk resistivity is measured at room temperature on the lanthanide element-containing films that are typically approximately 50 nm thick. The bulk resistivity typically increases for thinner films due to changes in the electron transport mechanism. The bulk resistivity also increases at higher temperatures.

In another alternative, the disclosed lanthanide element-containing film-forming compositions may be used as doping implantation agents. Part of the disclosed lanthanide element-containing film-forming composition may be deposited on top of the film to be doped.

### EXAMPLES

The following non-limiting examples are provided to further illustrate embodiments of the invention. However, the examples are not intended to be all inclusive and are not intended to limit the scope of the inventions described herein.

### Comparison Example

As stated above, Gd and Dy precursors, such as Gd(RCp)₂(R′-fmd) and Dy(RCp)₂(R′-fmd), with —(R′-fmd) ligand improve the volatility of the lanthanide element-containing precursors.

GdCp₂(iPr-fmd) and Dy(EtCp)₂(iPr-fmd) showed unique physical and chemical properties when they are compared to other precursors in Gd(iPrCp)₂(iPr-amd) and Dy(iPrCp)₂(iPr-amd) as described in Table 1. The highlighted feature of this series was huge improvement of volatility.

The vapor pressure of GdCp₂(iPr-fmd) and Dy(EtCp)₂(iPr-fmd) shows 1 Torr at 154° C. and 1 Torr at 151° C. respectively. These values are the highest value among all of Gd and Dy precursors for each Gd(RCp)₃, Gd(RCp)₂(iPr-amd) series and Dy(RCp)₂(iPr-fmd), Dy(RCp)₂(iPr-amd) series respectively. Here, “iPr-amd” represents iPrNC(CH₃)═NiPr ligand and “iPr-fmd” represents iPrNC(H)═NiPr ligand.

TABLE 1
Comparison of vapor pressure

| Precursors | Melting point | Vapor pressure |
|---|---|---|
| GdCp₂(iPr-fmd) | 65° C. | 1 Torr at 154° C. |
| Gd(iPrCp)₂(iPr-amd) | 55° C. | 1 Torr at 171° C. |
| Gd(iPrCp)₃ | 50° C. | 1 Torr at 200° C. |
| Dy(EtCp)₂(iPr-fmd) | <RT | 1 Torr at 151° C. |
| Dy(MeCp)₂(iPr-fmd) | 51° C. | 1 Torr at 163° C. |
| Dy(iPrCp)₂(iPr-amd) | <RT | 1 Torr at 165° C. |

### Example 1. Synthesis of GdCp₂(iPr-fmd)

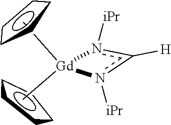

A solution of n-BuLi (23.75 mL of 1.6 M in hexane/38.0 mmol) was added dropwise to the Cp(H) (2.51 g/38.0 mmol) solution in 25 mL THF at −78° C. The mixture was allowed to warm up to room temperature (RT) for 3 hours with stirring forming a mixture of CpLi. A suspension of GdCl₃ (5.00 g/19.0 mmol) in 40 mL THF at −78° C. was added to the mixture of CpLi dropwise. The mixture was stirred and allowed to warm up to RT overnight to form a GdCp₂Cl. A solution of n-BuLi (11.88 mL of 1.6 M in hexane/19.0 mmol) was added dropwise to a iPr-fmd(H) (2.49 g/19.4 mmol) solution in 25 mL THF at −78° C., and then allowed to warm up to RT for 3 hours with stirring to give a mixture of Li(iPr-fmd). A suspension of Li(iPr-fmd) was added slowly to GdCp₂Cl crude mixture at −78° C. The crude mixture was warm up to RT with stirring for overnight to give a crude brown suspension. The organic solvents were removed under vacuum (ca. 45 mTorr) and 30 mL toluene was added. The brown suspension was filtered and solvent was removed under vacuum (ca. 45 mTorr) to give a crude brown sticky solid. It was then sublimed under vacuum with a cold finger. The crude brown sticky solid product was sublimed at ~90° C./30 mTorr to give 2.70 g (6.51 mmol) of white solid with 34% yield. The final white solid product was GdCp₂(iPr-fmd).

### Example 2. Synthesis of Dy(EtCp)₂(iPr-fmd)

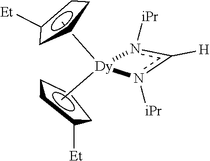

A solution of n-BuLi (8.96 mL of 2.5 M in hexane/22.4 mmol) was added dropwise to the EtCp(H) (2.11 g/22.4 mmol) solution in 25 mL THF at −78° C. The mixture was allowed to warm up to RT for 3 hours with stirring to give a mixture of EtCpLi. A suspension of DyCl₃ (3.00 g/11.2 mmol) in 40 mL THF at −78° C. was added to the mixture of EtCpLi dropwise. The mixture was stirred and allowed to warm up to RT overnight to give a Dy(EtCp)₂Cl. A solution of n-BuLi (4.48 mL of 2.5 M in hexane/11.2 mmol) was added dropwise to a iPr-fmd(H) (1.46 g/11.4 mmol) solution in 20 mL THF at −78° C. The mixture was allowed to warm up to RT for 3 hours with stirring to give a Li(iPr-fmd). A suspension of Li(iPr-fmd) was added slowly to Dy(EtCp)₂Cl crude mixture at −78° C. The crude mixture was warm up to RT with stir for overnight to give a crude brown suspension. The organic solvents were removed under vacuum (ca. 45 mTorr) and 30 mL toluene was added. The crude brown suspension was filtered and solvent was removed under vacuum (ca. 45 mTorr) to give a crude dark brown liquid. It was then distilled under vacuum with a short path distillation column. A small precut was isolated (a few mL) at 180° C./40 mTorr and the main material was distilled at around 190° C./40 mTorr (head column 60° C.) to give 2.2 g (4.62 mmol) of yellow liquid with 41% yield.

¹H NMR (ppm, C₆D₆): 294.24 (s, 1H), 289.89 (s, 4H), 205.34 (s, 4H), −28.41 (s, 2H), −33.84 (s, 4H), −48.41 (s, 6H), −180.38 (s, 12H). The yellow liquid was Dy(EtCp)₂(iPr-fmd).

### Example 3. Synthesis of Dy(MeCp)₂(iPr-fmd)

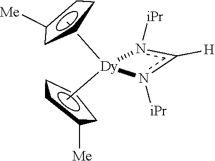

A solution of n-BuLi (8.96 mL of 2.5 M in hexane/22.4 mmol) was added dropwise to the MeCp(H) (1.79 g/22.4 mmol) solution in 25 mL THF at −78° C. The mixture was allowed to warm up to RT for 3 hours with stirring to give a MeCpLi. A suspension of DyCl₃ (3.00 g/11.2 mmol) in 40 mL THF at −78° C. was added to a mixture of MeCpLi dropwise. The mixture was stirred and allowed to warm up to RT overnight to give a Dy(MeCp)₂Cl. A solution of n-BuLi (4.48 mL of 2.5 M in hexane/11.2 mmol) was added dropwise to a iPr-fmd(H) (1.46 g/11.4 mmol) solution in 20 mL THF at −78° C. The mixture was allowed to warm up to RT for 3 hours with stirring to give a Li(iPr-fmd). A suspension of Li(iPr-fmd) was added slowly to Dy(MeCp)₂Cl crude mixture at −78° C. The mixture was warm up to RT with stirring for overnight to give a crude brown suspension. The organic solvents were removed under vacuum (ca. 45 mTorr) and 30 mL toluene was added. The brown suspension was filtered and solvent was removed under vacuum (ca. 45 mTorr) to give a crude brown sticky solid. It was then distilled under vacuum with a short path distillation column. A small precut was isolated (a few mL) at 170° C./40 mTorr and the main material was distilled at around 180° C./40 mTorr (head column 60° C.) to give 1.1 g (2.46 mmol) of yellow liquid with 22% yield. This product was changed to yellow solid immediately in the flask.

¹H NMR (ppm, C₆D₆): 301.64 (s, 1H), 297.05 (s, 4H), 162.10 (s, 4H), 11.79 (s, 6H), −22.80 (s, 2H), −183.24 (s, 12H). The yellow solid was Dy(MeCp)₂(iPr-fmd).

It will be understood that many additional changes in the details, materials, steps, and arrangement of parts, which have been herein described and illustrated in order to explain the nature of the invention, may be made by those skilled in the art within the principle and scope of the invention as expressed in the appended claims. Thus, the present invention is not intended to be limited to the specific embodiments in the examples given above and/or the attached drawings.

While embodiments of this invention have been shown and described, modifications thereof may be made by one skilled in the art without departing from the spirit or teaching of this invention. The embodiments described herein are exemplary only and not limiting. Many variations and modifications of the composition and method are possible and within the scope of the invention. Accordingly, the scope of protection is not limited to the embodiments described herein, but is only limited by the claims which follow, the scope of which shall include all equivalents of the subject matter of the claims.

What is claimed is:

1. A method of forming a lanthanide element-containing film on a substrate, the method comprising the steps of:
exposing the substrate to a vapor of a lanthanide element-containing film forming composition that contains a lanthanide element-containing precursor having the formula: 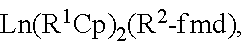
wherein R²-fmd is a formamidinate group, R²NC(H)═NR², wherein the R² group can be the same or different; Cp is cyclopentadienyl; Ln is a lanthanide element selected from Sc, Y, La, Ce, Pr, Nd, Pm, Sm, Eu, Gd, Tb, Dy, Ho, Er, Tm, Yb or Lu; R¹ and R² each are independently selected from a hydrogen atom, a C₁ to C₅ linear or branched alkyl-group, a C₃ to C₅ cyclic alkyl-group; and
depositing at least part of the lanthanide element-containing precursor onto the substrate to form the lanthanide element-containing film via a vapor deposition process.

2. The method of claim 1, wherein R² is selected from Me, Et, nPr, iPr, nBu, iBi, sBu or tBu.

3. The method of claim 1, wherein the lanthanide element-containing precursor is GdCp₂(iPr-fmd).

4. The method of claim 1, wherein the lanthanide element-containing precursor is Dy(EtCp)₂(iPr-fmd).

5. The method of claim 1, wherein the lanthanide element-containing precursor is Dy(MeCp)₂(iPr-fmd).

6. The method of claim 1, further comprising
exposing the substrate to a co-reactant selected from an oxidizer agent or a nitrogen agent.

7. The method of claim 5, wherein the co-reactant is selected from O₃, O₂, H₂O, H₂O₂, D₂O, ROH wherein R═C₁-C₁₀ linear or branched hydrocarbon, or combination thereof.

8. The method of claim 1, wherein the lanthanide element-containing precursor is volatile.

9. The method of claim 1, wherein the lanthanide element-containing precursor is mixed with a solvent.

10. The method of claim 8, wherein the solvent is a substituted or unsubstituted hydrocarbon selected from alkanes, alkenes, alkynes; alcohols selected from alkyl alcohols, amino alcohols; or amines selected from primary-, secondary-, tertiary-amines; tetrahydrofuran; dichloromethane; ethyl acetate; butyl acetate; acetonitrile; dimethylformamide.

11. The method of claim 9, wherein the substituted or unsubstituted hydrocarbons include octane, ethyl benzene, xylene, mesitylene, decalin, decane, dodecane.

12. The method of claim 8, wherein a concentration of the lanthanide element-containing precursor in the solvent ranges from approximately 50% w/w and approximately 100.0% w/w.

13. The method of claim 1, wherein the substrate is exposed to the vapor of the lanthanide element-containing film forming composition at a temperature ranging from 150° C. to approximately 500° C.

14. The method of claim 1, wherein the vapor deposition process is a MOCVD process, or an ALD process selected from a thermal ALD, spatial ALD, temporal ALD, or plasma ALD process.

15. The method of claim 1, wherein the lanthanide element-containing film is a GyO film or a GaO film.

16. A method of forming a conductive layer for a thin-film transistor (TFT) or transducer on a substrate, the method comprising the steps of:
exposing the substrate to a vapor of a lanthanide element-containing film forming composition that contains a lanthanide element-containing precursor having the formula: 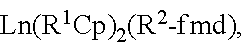
wherein R²-fmd is a formamidinate group, R²NC(H)═NR², wherein the R² group can be the same or different; Cp is cyclopentadienyl; Ln is a lanthanide element selected from Sc, Y, La, Ce, Pr, Nd, Pm, Sm, Eu, Gd, Tb, Dy, Ho, Er, Tm, Yb or Lu; R¹ and R² each are independently selected from a hydrogen atom, a C₁ to C₅ linear or branched alkyl-group, a C₃ to C₅ cyclic alkyl-group; and
depositing at least part of the lanthanide element-containing precursor onto the substrate to form the conductive layer for a thin-film transistor (TFT) or transducer via a vapor deposition process.

17. The method of claim 16, wherein the lanthanide element-containing precursor is selected from the group consisting of GdCp₂(iPr-fmd), Dy(EtCp)₂(iPr-fmd) and Dy(MeCp)₂(iPr-fmd).

18. A lanthanide element-containing film-forming composition for forming a lanthanide element-containing film, the composition comprising:
i) at least one lanthanide element-containing precursor, wherein the lanthanide element-containing precursor having the formula: 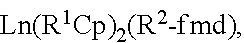
wherein R²-fmd is a formamidinate group, R²NC(H)═NR², wherein the R² group can be the same or different; Cp is cyclopentadienyl; Ln is a lanthanide element selected from Sc, Y, La, Ce, Pr, Nd, Pm, Sm, Eu, Gd, Tb, Dy, Ho, Er, Tm, Yb or Lu; R¹ and R² each are independently selected from a hydrogen atom, a C₁ to C₅ linear or branched alkyl-group, a C₃ to C₅ cyclic alkyl-group;
ii) a co-reactant; and
iii) a solvent,
wherein the lanthanide-containing film-forming composition is capable of forming the lanthanide element-containing film.

19. The lanthanide element-containing film-forming composition of claim 18, wherein the at least one lanthanide element-containing precursor is selected from the group consisting of GdCp₂(iPr-fmd), Dy(EtCp)₂(iPr-fmd) and Dy(MeCp)₂(iPr-fmd).

20. The lanthanide element-containing film-forming composition of claim 18, wherein the lanthanide element-containing precursor is volatile.
